(19) United States
(12) Patent Application Publication
(10) Pub. No.: US 2026/0159637 A1
(43) Pub. Date: Jun. 11, 2026

(54) EPOXY RESIN COMPOSITION FOR ENCAPSULATION OF SEMICONDUCTOR DEVICES AND SEMICONDUCTOR DEVICE ENCAPSULATED USING THE SAME

(71) Applicant: SAMSUNG SDI CO., LTD., Yongin-si (KR)

(72) Inventors: Yong Han CHO, Suwon-si (KR); Dong Hwan LEE, Suwon-si (KR); Tae Shin EOM, Suwon-si (KR); Seung Hee Huh, Suwon-si (KR); Jong Gu KANG, Suwon-si (KR)

(73) Assignee: SAMSUNG SDI CO., LTD., Yongin-si (KR)

(21) Appl. No.: 19/410,219

(22) Filed: Dec. 5, 2025

(30) Foreign Application Priority Data
Dec. 6, 2024 (KR) 10-2024-0180068

(51) Int. Cl. C08G 59/24; C08G 59/62; C08G 59/68; C08K 3/22; C08K 7/18; H10W 74/47

(52) U.S. Cl. CPC C08G 59/245; C08G 59/621; C08G 59/688; C08K 3/22; C08K 7/18; H10W 74/473; C08K 2003/2227; C08K 2201/005

(57) ABSTRACT

Disclosed herein are an epoxy resin composition for encapsulation of semiconductor devices, and a semiconductor device encapsulated using the epoxy resin composition. The epoxy resin composition includes an epoxy resin, a curing agent, inorganic fillers, and a curing catalyst.

### CROSS-REFERENCE TO RELATED APPLICATION

The present application claims priority to Korean Patent Application No. 10-2024-0180068, filed on Dec. 6, 2024 in the Korean Intellectual Property Office, the entire disclosure of which is incorporated herein by reference.

### FIELD OF THE DISCLOSURE

The present disclosure relates to an epoxy resin composition for encapsulation of semiconductor devices and a semiconductor device encapsulated using the epoxy resin composition.

### DESCRIPTION OF THE RELATED ART

The degree of integration of semiconductor devices is increasing, and in a semiconductor apparatus in which a stack of high-density semiconductor devices is encapsulated in a small and thin package, failure, such as cracking or malfunction of the package, can frequently occur due to heat generation during operation of the semiconductor device.

As a solution for challenges related to heat generation, a heatsink formed of a heat dissipation material, such as a metal, is bonded to a semiconductor package upon molding of an epoxy resin for encapsulation. However, such a heatsink is applicable only to some packages, such as, e.g., a fine pitch ball grid array (FBGA), a quad flat package (QFP), and the like, and experiences a reduction in productivity due to the need for additional assembly processes during assembly and increase in cost due to high costs of the heatsink. Therefore, there is a demand for an epoxy resin molding material for encapsulation of semiconductor devices, which has high thermal conductivity and desired heat dissipation capacity. Some semiconductor packages employ include aluminum oxide (alumina).

Alumina has a thermal conductivity in a range of about 25 W/m·K to about 30 W/m·K, whereas the resin used in sealed semiconductor devices has a poor thermal conductivity of about 0.2 W/m·K, thereby providing limitation in improvement in thermal conductivity. In addition, copper, aluminum, and silver particles with high thermal conductivity typically have poor insulation performance, and aluminum nitride, boron nitride, and silicon carbide fillers with relatively desired insulation performance cannot increase the filling rate due to poor flowability. Although there are efforts to improve thermal conductivity of resins, commercialization of insulating and thermosetting compressed resin sealed semiconductor materials has not yet been achieved.

To impart high thermal conductivity to resin compositions or epoxy molding compounds (EMC), a method of using aluminum oxide (alumina), which has a higher thermal conductivity (in a range of about 25 W/m·K to about 30 W/m·K) than silicon oxide, is typically known. However, typical resins used in resin compositions for encapsulation of semiconductors have a low thermal conductivity of about 0.2 W/m·K, which makes it difficult to obtain a resin composition having a thermal conductivity of about 6 W/m·K or more.

Use of large amounts of inorganic fillers in a resin composition for encapsulation of semiconductors is likely to cause wire sweep due to increase in viscosity of the composition, can cause void defects due to difficulty in forming a package caused by reduction in fluidity of the composition, and provides limitation in improvement in filling rate. In addition, since heat generated during operation of a semiconductor device inevitably passes through a resin on a heat transfer path, high thermal conductivity of the fillers cannot ensure effective heat transfer if the resin has low thermal conductivity.

### SUMMARY

An example aspect of the present disclosure includes an epoxy resin composition for encapsulation of semiconductor devices that provides desired or improved heat dissipation due to high thermal conductivity while improving reliability through improvement in toughness.

An example aspect of the present disclosure includes an epoxy resin composition for encapsulation of semiconductor devices.

The epoxy resin composition for encapsulation of semiconductor devices includes at least one of an epoxy resin, a curing agent, inorganic fillers, and a curing catalyst, wherein the epoxy resin includes an epoxy resin represented by Formula 1:

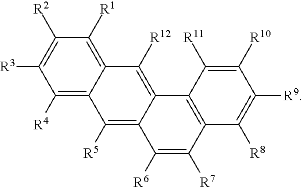

In Formula 1 above, R¹ to R¹² each independently is or includes hydrogen, a substituted or unsubstituted C₁ to C₂₀ alkyl group, a substituted or unsubstituted C₆ to C₃₀ aryl group, a substituted or unsubstituted C₆ to C₃₀ aryloxy group, a substituted or unsubstituted C₃ to C₃₀ heteroaryl group, a substituted or unsubstituted C₃ to C₃₀ heterocycloalkyl group, a substituted or unsubstituted C₇ to C₃₀ arylalkyl group, a substituted or unsubstituted C₁ to C₃₀ heteroalkyl group, or a compound represented by Formula 2,
at least two of R¹ to R¹² being a compound represented by Formula 2:

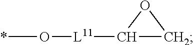

where * is a linking site of an element and L¹¹ is or includes a substituted or unsubstituted C₄ to C₁₀ alkylene group.

Another aspect of the present disclosure includes a semiconductor device.

The semiconductor device is encapsulated using the epoxy resin composition for encapsulation of semiconductor devices.

Example embodiments of the present disclosure include an epoxy resin composition for encapsulation of semiconductor devices that provides desired or improved heat dissipation due to high thermal conductivity while improving reliability through improvement in toughness.

### DETAILED DESCRIPTION

Hereinafter, example embodiments of the present disclosure are described in detail such that the present disclosure can be readily implemented by a person having ordinary knowledge in the art. It should be understood that the present disclosure may be embodied in various ways and is not limited to the following example embodiments.

As used herein to represent a specific numerical range, “X to Y” means “greater than or equal to X and less than or equal to Y.”

As used herein, the term “substituted” in the expression “substituted or unsubstituted” means that at least one hydrogen atom of a corresponding functional group is substituted with a hydroxyl group, an amino group, a nitro group, a cyano group, a C₁ to C₂₀ alkyl group, a C₁ to C₂₀ haloalkyl group, a C₆ to C₃₀ aryl group, a C₃ to C₃₀ heteroaryl group, a C₃ to C₁₀ cycloalkyl group, a C₃ to C₁₀ heterocycloalkyl group, a C₇ to C₃₀ arylalkyl group, or a C₁ to C₃₀ heteroalkyl group.

Unless stated otherwise, a formula described herein may be considered to have a hydrogen atom bonded to a structure thereof.

When the terms “about” or “substantially” are used in this specification in connection with a numerical value, it is intended that the associated numerical value include a tolerance of ±10% around the stated numerical value. When ranges are specified, the range includes all values therebetween such as increments of 0.1%.

An epoxy resin composition for encapsulation of semiconductor devices according to one example embodiment includes an epoxy resin, a curing agent, inorganic fillers, and a curing catalyst, wherein the epoxy resin includes an epoxy resin represented by Formula 1 described below.

The epoxy resin represented by Formula 1 has high thermal conductivity and improved toughness to secure desired heat dissipation while improving reliability.

### Epoxy Resin

The epoxy resin includes the epoxy resin represented by Formula 1 below.

The epoxy resin represented by Formula 1 has high thermal conductivity and improved toughness to achieve desired heat dissipation while improving reliability.

The epoxy resin represented by Formula 1 has a benzanthracene parent nucleus instead of a tetracene parent nucleus having a structure in which phenyl groups are linked in a straight chain, and thus has a relatively high solubility and can be used in the composition according to the present disclosure.

In one example embodiment, the epoxy resin may be represented by Formula 1 below:

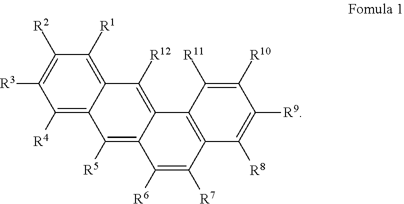

In Formula 1, R¹ to R¹² each independently is or includes hydrogen, a substituted or unsubstituted C₁ to C₂₀ alkyl group, a substituted or unsubstituted C₆ to C₃₀ aryl group, a substituted or unsubstituted C₆ to C₃₀ aryloxy group, a substituted or unsubstituted C₃ to C₃₀ heteroaryl group, a substituted or unsubstituted C₃ to C₃₀ heterocycloalkyl group, a substituted or unsubstituted C₇ to C₃₀ arylalkyl group, a substituted or unsubstituted C₁ to C₃₀ heteroalkyl group, or a compound represented by Formula 2 below, at least two of R¹ to R¹² being a compound represented by Formula 2:

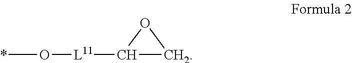

wherein Formula 2, * is a linking site of an element and L¹¹ is or includes a substituted or unsubstituted C₄ to C₁₀ alkylene group.

The composition may include at least one, for example, at least two epoxy resins of Formula 1.

In one example embodiment, each of R¹ to R¹² in Formula 1 independently is or includes hydrogen, a substituted or unsubstituted C₁ to C₂₀ alkyl group, or a compound represented by Formula 2, and at least two of R¹ to R¹² may be or include a compound represented by Formula 2.

In one example embodiment, at least one of R¹ to R⁴ in Formula 1 may be or include a compound represented by Formula 2. For example, R³ in Formula 1 is or includes a compound represented by Formula 2.

In one example embodiment, at least one of R⁸ to R¹¹ in Formula 1 may be or include a compound represented by Formula 2. For example, R³ in Formula 1 may be or include a compound represented by Formula 2.

In one example embodiment, R¹, R², R⁴ to R⁸, and R¹⁰ to R¹² in Formula 1 may each independently be or include hydrogen or a substituted or unsubstituted C₁ to C₂₀ alkyl group, for example, an unsubstituted C₁ to C₈ alkyl group.

In another example embodiment, at least one of R¹ to R⁴ in Formula 1 may be or include a compound represented by Formula 2. For example, R³ in Formula 1 is or includes a compound represented by Formula 2.

In another example embodiment, at least one of R⁶ to R⁷ in Formula 1 may be or include a compound represented by Formula 2. For example, R⁷ in Formula 1 is or includes a compound represented by Formula 2.

In other example embodiments, R¹, R², R⁴ to R⁶, and R⁸ to R¹² in Formula 1 may each independently be or include hydrogen or a substituted or unsubstituted C₁ to C₂₀ alkyl group, for example, a substituted C₁ to C₈ alkyl group.

For example, the epoxy resin represented by Formula 1 may include at least one of the compounds represented by Formulas 1-1 to 1-6:

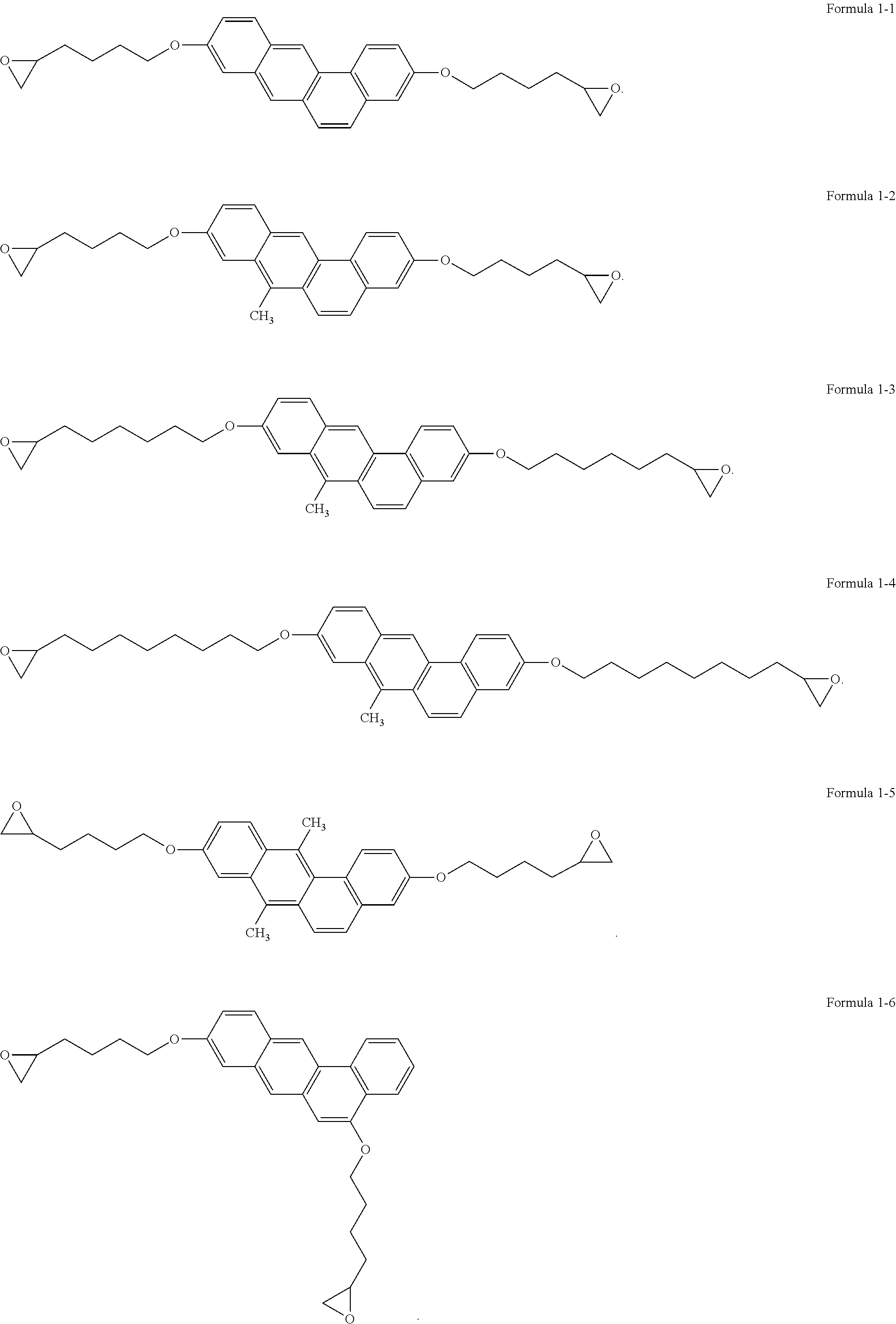 [SMILES: c1cc2cc3c(ccc4cc(OCCCCC5CO5)ccc43)cc2cc1OCCCCC1CO1 ; Cc1c2cc(OCCCCC3CO3)ccc2cc2c1ccc1cc(OCCCCC3CO3)ccc12 ; Cc1c2cc(OCCCCCCC3CO3)ccc2cc2c1ccc1cc(OCCCCCCC3CO3)ccc12 ; Cc1c2cc(OCCCCCCCCC3CO3)ccc2cc2c1ccc1cc(OCCCCCCCCC3CO3)ccc12 ; Cc1c2cc(OCCCCC3CO3)ccc2c(C)c2c1ccc1cc(OCCCCC3CO3)ccc12 ; c1ccc2c(c1)c(OCCCCC1CO1)cc1cc3cc(OCCCCC4CO4)ccc3cc12]

The epoxy resin composition may include at least one of the epoxy resins represented by Formula 1, and the epoxy resin represented by Formula 1 may be present in an amount in a range of about 0.1 wt % to about 17 wt %, for example, 2 wt % to 17 wt %, for example, 2 wt % to 10 wt %, in the epoxy resin composition. Within the above range, the epoxy resin composition can exhibit improved heat dissipation properties without deterioration in curability.

The epoxy resin represented by Formula 1 may be prepared by any typical method of preparing epoxy resins known to those skilled in the art.

For example, the epoxy resin represented by Formula 1 may be prepared according to the following reaction scheme:

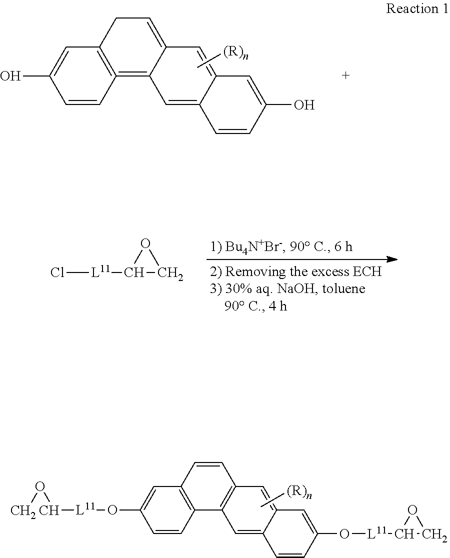

In Reaction 1, L¹¹ is the same as defined in Formula 2 above, and
R is or includes a substituted or unsubstituted C₁ to C₂₀ alkyl group, a substituted or unsubstituted C₆ to C₃₀ aryl group, a substituted or unsubstituted C₆ to C₃₀ aryloxy group, a substituted or unsubstituted C₃ to C₃₀ heteroaryl group, a substituted or unsubstituted C₃ to C₃₀ heterocyloalkyl group, a substituted or unsubstituted C₇ to C₃₀ arylakyl group, or a substituted or unsubstituted C₁ to C₃₀ heteroalkyl group, and
n is an integer in a range of about 0 to about 10.

The epoxy resin of the epoxy resin composition may include, or consist solely of, the epoxy resin represented by Formula 1 above. However, the present disclosure is not limited thereto, and the epoxy resin composition may further include an epoxy resin other than the epoxy resin represented by Formula 1 without affecting the desired effects of the present disclosure. For descriptive convenience, the epoxy resin represented by Formula 1 is referred to as a first epoxy resin and the epoxy resin other than the epoxy resin represented by Formula 1 is referred to as a second epoxy resin.

The second epoxy resin is or includes an epoxy resin containing at least two epoxy groups in a molecular structure thereof, and may include at least one of bisphenol A epoxy resins, bisphenol F epoxy resins, phenol novolac epoxy resins, tert-butyl catechol epoxy resins, naphthalene epoxy resins, glycidyl amine epoxy resins, cresol novolac epoxy resins, biphenyl epoxy resins, phenol aralkyl epoxy resins, linear aliphatic epoxy resins, cycloaliphatic epoxy resins, heterocyclic epoxy resins, spirocyclic epoxy resins, cyclohexanedimethanol epoxy resins, trimethylol epoxy resins, halogenated epoxy resins, and the like. As the second epoxy resin, these epoxy resins may be used alone, or as a mixture thereof.

The epoxy resin may be present in an amount in a range of about 2 wt % to about 17 wt %, for example, 2 wt % to 10 wt %, in the epoxy resin composition. Within the above range, the composition can avoid reduction in curability.

### Curing Agent

The curing agent may include at least one of polyfunctional phenol resins, aralkyl type phenol resins, novolac type phenol resins, Xylok type phenol resins, cresol novolac type phenol resins, naphthol-type phenol resins, terpene-type phenol resins, dicyclopentadiene phenol resins, novolac type phenol resins synthesized from bisphenol A and resol, and the like; polyhydric phenol compounds including tris(hydroxyphenyl) methane, dihydroxybiphenyl, and the like; acid anhydrides including maleic anhydride, phthalic anhydride, and the like; and aromatic amines including metaphenylenediamine, diaminodiphenylmethane, diaminodiphenylsulfone, and the like. For example, the curing agent includes a Xylok type phenol resin or an aralkyl type phenol resin.

The curing agent may be present in an amount in a range of about 0.5 wt % to about 13 wt % in the epoxy resin composition. Within the above range, the composition can avoid a reduction in curability.

### Inorganic Fillers

The inorganic fillers improve mechanical properties of the epoxy resin composition while reducing internal stress of the epoxy resin composition.

The inorganic fillers may include at least one of fused silica, crystalline silica, calcium carbonate, magnesium carbonate, alumina, magnesia, clay, talc, calcium silicate, titanium oxide, antimony oxide, and glass fiber.

For example, the inorganic fillers include fused silica having a low coefficient of linear expansion for low stress. The fused silica refers to amorphous silica having a specific gravity of about 2.3 or less and may include amorphous silica obtained by melting crystalline silica or synthesized from various raw materials. Although the fused silica is not limited to a particular shape and size, the inorganic fillers may include about 40 wt % to about 100 wt % of a fused silica mixture including about 50 wt % to about 99 wt % of spherical fused silica having an average particle diameter in a range of about 5 μm to about 30 μm, and about 1 wt % to about 50 wt % of spherical fused silica having an average particle diameter in a range of about 0.001 μm to about 1 μm. Furthermore, the maximum particle diameter of the inorganic fillers may be adjusted to about 45 μm, about 55 μm, about 75 μm, and the like depending on application.

The content of the inorganic fillers in the composition may be varied depending on properties required for the composition, such as thermal conductivity, moldability, low stress, and strength at high temperature. In some example embodiments, the inorganic fillers may be present in an amount in a range of about 50 wt % to about 95 wt %, for example 70 wt % to 95 wt %, and for example 85 wt % to 95 wt %, in the epoxy resin composition. Within this range, the epoxy resin composition can have desired properties in terms of flame retardancy, fluidity, and reliability.

### Curing Catalyst

The curing catalyst may include at least one of a tertiary amine compound, an organometallic compound, an organophosphorus compound, an imidazole compound, or a boron compound. The tertiary amine compound may include, for example, at least one of benzyldimethylamine, triethanolamine, triethylenediamine, diethylaminoethanol, tri (dimethylaminomethyl) phenol, 2,2-(dimethylaminomethyl) phenol, 2,4,6-tris(diaminomethyl) phenol, tri-2-ethyl hexanoate, and the like. The organometallic compound may include, for example, at least one of chromium acetylacetonate, zinc acetylacetonate, nickel acetylacetonate, and the like. The organophosphorus compound may include, for example, at least one of triphenylphosphine, tris-4-methoxyphosphine, triphenylphosphine-triphenylborane, triphenylphosphine-1,4-benzoquinone adducts, and the like. The imidazole compound may include, for example, at least one of 2-methylimidazole, 2-phenylimidazole, 2-aminoimidazole, 2-methyl-1-vinylimidazole, 2-ethyl-4-methylimidazole, 2-heptadecyl imidazole, and the like. The boron compound may include, for example, at least one of triphenylphosphine tetraphenyl borate, tetraphenylboron salts, trifluoroborane-n-hexylamine, trifluoroborane monoethylamine, tetrafluoroborane triethylamine, tetrafluoroborane amine, and the like. Besides these compounds, 1,5-diazabicyclo[4.3.0]non-5-ene (DBN), 1,8-diazabicyclo[5.4.0]undec-7-ene (DBU), and phenol novolac resin salts may be used as the curing catalyst.

The curing catalyst may be provided in the form of an adduct prepared by pre-reacting the curing catalyst with the epoxy resin or the curing agent.

The curing catalyst may be present in an amount in a range of about 0.01 wt % to about 5 wt % in the epoxy resin composition. Within this range, the curing catalyst can promote curing of the composition without sacrificing fluidity of the composition.

The epoxy resin composition may further include typical additives used in epoxy resin compositions for encapsulation of semiconductor devices. In some example embodiments, the additives may include at least one of a coupling agent, a release agent, a colorant, a stress relieving agent, a crosslinking enhancer, and a leveling agent.

The coupling agent increases interfacial strength between the epoxy resin and the inorganic fillers through reaction with the epoxy resin and the inorganic fillers and may include, for example, a silane coupling agent. The silane coupling agent may include any silane coupling agent that can increase interfacial strength between the epoxy resin and the inorganic fillers through reaction with the epoxy resin and the inorganic fillers, without limitation. The silane coupling agent may include, for example, at least one of epoxy silane, amino silane, ureido silane, mercapto silane, alkyl silane, and the like. These coupling agents may be used alone or in combination thereof. The coupling agent may be present in an amount in a range of about 0.01 wt % to about 5 wt %, for example 0.05 wt % to 3 wt %, in the epoxy resin composition for encapsulation of semiconductor devices. Within the above range, a cured product of the epoxy resin composition can exhibit enhanced strength.

The release agent may include at least one of paraffin wax, ester wax, higher fatty acid, a metallic salt of higher fatty acid, natural fatty acid, and a metallic salt of natural fatty acid. The release agent may be present in an amount in a range of about 0.1 wt % to about 1 wt % in the epoxy resin composition.

The colorant may include carbon black. The colorant may be present in an amount in a range of about 0.1 wt % to about 1 wt % in the epoxy resin composition.

The stress relieving agent may include at least one of modified silicone oils, silicone elastomers, silicone powders, and silicone resins, without being limited thereto. The stress relieving agent may be optionally present in an amount in a range of about 2 wt % or less, for example, 1 wt % or less, for example 0.1 wt % to 1 wt %, in the epoxy resin composition.

The additives may be present in an amount in a range of about 0.1 wt % to about 5 wt %, for example, 0.1 wt % to 3 wt %, in the epoxy resin composition.

Although a method of preparing the epoxy resin composition is not particularly restricted, the epoxy resin composition may be prepared by uniformly mixing the aforementioned components in a Henschel mixer or a Lödige mixer, melt-kneading the mixture in a roll mill or a kneader at a temperature in a range of about 90° C. to about 120° C., and subjecting the resulting product to cooling and pulverization.

In accordance with another aspect of the present disclosure, a semiconductor device is encapsulated using the epoxy resin composition for encapsulation of semiconductor devices according to the present disclosure. The semiconductor device may be encapsulated with the epoxy resin composition by any suitable method known in the art, such as, e.g., transfer molding, injection molding, casting, or compression molding, without being limited thereto. In one example embodiment, the semiconductor device may be encapsulated with the epoxy resin composition by low-pressure transfer molding. In another example embodiment, the semiconductor device may be encapsulated with the epoxy resin composition by compression molding.

The present disclosure is described in more detail below with reference to some examples. However, it should be noted that these examples are provided for illustration only, and are not to be construed in any way as limiting the present disclosure.

### Preparative Example 1: Preparation of Epoxy Resin 1-1

In the presence of TBAB (tetra-n-butylammonium bromide), benz[a]anthracene-3,9-diol (26 g, 0.1 mol) and an excess (300 g) of 2-(4-chlorobutyl) oxirane were heated (to 90° C.) under solvent-free conditions for 6 hours and then cooled to room temperature, followed by removing the remaining unreacted 2-(4-chlorobutyl) oxirane using a Kugelrohr distiller. An aqueous NaOH solution and toluene were then added to a resulting product obtained through synthesis, followed by heating to 90° C. for 4 hours, thereby preparing an epoxy resin represented by Formula 1-1 above in 75% yield through intramolecular Williamson ether synthesis. ¹H NMR (400 MHz, CDCl₍₃₎) δ 8.93 (s, 1H), 8.82 (s, 1H), 8.12 (m, 1H), 7.71 (m, 2H), 7.65-7.60 (m, 2H), 7.39 (m, 1H), 7.05-6.97 (m, 2H), 4.04 (m, 4H), 2.60-2.35 (m, 6H) 1.71 (m, 4H) 1.42-1.25 (m, 8H) ppm; ¹³C NMR (100 MHz, CDCl₍₃₎) δ 157.3, 155.9, 134.0, 133.4, 131.5, 129.8, 129.6, 129.5, 126.6, 126.5, 125.1, 123.1, 123.0, 118.0, 111.2, 109.6, 105.9, 68.9, 68.8, 52.3, 47.9, 33.5, 33.2, 29.4, 21.6 ppm; GC-MS m/z=456 (M+); Anal. Calcd for C₃₀H₃₂O₄: C, 78.92; H, 7.06. Found: C, 78.53; H, 7.48.

### Preparative Example 2: Preparation of Epoxy Resin 1-2

In the presence of TBAB (tetra-n-butylammonium bromide), 7-methylbenz[a]anthracene-3,9-diol (27 g, 0.1 mol) and an excess (300 g) of 2-(4-chlorobutyl) oxirane were heated (to 90° C.) under solvent-free conditions for 6 hours and then cooled to room temperature, followed by removing the remaining unreacted 2-(4-chlorobutyl) oxirane using a Kugelrohr distiller. An aqueous NaOH solution and toluene were then added to a resulting product obtained through synthesis, followed by heating to 90° C. for 4 hours, thereby preparing an epoxy resin represented by Formula 1-2 above in 75% yield through intramolecular Williamson ether synthesis. ¹H NMR (400 MHz, CDCl₃) δ 8.82 (s, 1H), 8.74 (m, 1H), 7.71 (s, 2H), 7.65-7.60 (m, 2H), 7.39 (m, 1H), 7.05 (m, 1H), 6.98 (s, 1H), 4.04 (m, 4H), 2.65-2.35 (m, 9H) 1.71 (m, 4H) 1.43-1.25 (m, 8H) ppm; ¹³C NMR (100 MHz, CDCl₍₃₎) δ 157.4, 155.7, 137.5, 134.0, 133.4, 131.5, 129.8, 129.6, 129.5, 126.6, 126.5, 125.1, 123.1, 123.0, 118.0, 116.2, 111.2, 109.6, 105.9, 68.9, 52.3, 47.9, 33.5, 29.4, 21.6, 20.8 ppm; GC-MS m/z=470 (M+); Anal. Calcd for C₃₁H₃₄O₄: C, 79.12; H, 7.28. Found: C, 79.34; H, 7.52.

### Preparative Example 3: Preparation of Epoxy Resin 1-3

In the presence of TBAB (tetra-n-butylammonium bromide), 7-methylbenz[a]anthracene-3,9-diol (27 g, 0.1 mol) and an excess (300 g) of 2-(6-chlorohexyl) oxirane were heated (to 90° C.) under solvent-free conditions for 6 hours and then cooled to room temperature, followed by removing the remaining unreacted 2-(6-chlorohexyl) oxirane using a Kugelrohr distiller. A NaOH aqueous solution and toluene were then added to a resulting product obtained through synthesis, followed by heating to 90° C. for 4 hours, thereby preparing an epoxy resin represented by Formula 1-3 above in 68% yield through intramolecular Williamson ether synthesis. ¹H NMR (400 MHz, CDCl₍₃₎) δ 8.82 (s, 1H), 8.74 (m, 1H), 7.71 (s, 2H), 7.65-7.60 (m, 2H), 7.39 (m, 1H), 7.05 (m, 1H), 6.98 (s, 1H), 4.04 (m, 4H), 2.65-2.35 (m, 9H) 1.71 (m, 4H) 1.45-1.20 (m, 16H) ppm; ¹³C NMR (100 MHz, CDCl₍₃₎) δ 157.4, 155.7, 137.5, 134.0, 133.4, 131.5, 129.8, 129.6, 129.5, 126.6, 126.5, 125.1, 123.1, 123.0, 118.0, 116.2, 111.2, 109.6, 105.9, 68.9, 52.3, 47.9, 33.5, 29.4, 25.3, 25.1, 21.6, 20.8 ppm; GC-MS m/z=526 (M+); Anal. Calcd for C₃₅H₄₂O₄: C, 79.81; H, 8.04. Found: C, 79.59; H, 8.50.

### Preparative Example 4: Preparation of Epoxy Resin 1-4

In the presence of TBAB (tetra-n-butylammonium bromide), 7-methylbenz[a]anthracene-3,9-diol (27 g, 0.1 mol) and an excess (340 g) of 2-(8-chlorooctyl) oxirane were heated (to 90° C.) under solvent-free conditions for 6 hours and then cooled to room temperature, followed by removing the remaining unreacted 2-(8-chlorooctyl) oxirane using a Kugelrohr distiller. An aqueous NaOH solution and toluene were then added to a resulting product obtained through synthesis, followed by heating to 90° C. for 4 hours, thereby preparing an epoxy resin represented by Formula 1-4 above in 75% yield through intramolecular Williamson ether synthesis. ¹H NMR (400 MHz, CDCl₍₃₎) δ 8.82 (s, 1H), 8.74 (m, 1H), 7.71 (s, 2H), 7.65-7.60 (m, 2H), 7.39 (m, 1H), 7.05 (m, 1H), 6.98 (s, 1H), 4.04 (m, 4H), 2.65-2.35 (m, 9H) 1.71 (m, 4H) 1.42 (m, 4H), 1.32-1.26 (m, 20H) ppm; ¹³C NMR (100 MHz, CDCl₍₃₎) δ 157.3, 155.5, 137.6, 134.1, 133.3, 131.5, 129.8, 129.7, 129.6 129.5, 126.6, 126.5, 125.1, 123.1, 123.0, 118.0, 116.2, 111.2, 109.6, 105.9, 68.9, 52.3, 47.9, 33.5, 29.4, 29.3, 29.2, 25.3, 25.1, 21.5, 20.7 ppm; GC-MS m/z=582 (M+); Anal. Calcd for C₃₉H₅₀O₄: C, 80.37; H, 8.65. Found: C, 80.39; H, 8.27.

### Preparative Example 5: Preparation of Epoxy Resin 1-5

In the presence of TBAB (tetra-n-butylammonium bromide), 7-dimethylbenz[a]anthracene-3,9-diol (29 g, 0.1 mol) and an excess (300 g) of 2-(4-chlorobutyl) oxirane were heated (to 90° C.) under solvent-free conditions for 6 hours and then cooled to room temperature, followed by removing the remaining unreacted 2-(4-chlorobutyl) oxirane using a Kugelrohr distiller. An aqueous NaOH solution and toluene were then added to a resulting product obtained through synthesis, followed by heating to 90° C. for 4 hours, thereby preparing an epoxy resin represented by Formula 1-5 above in 75% yield through intramolecular Williamson ether synthesis. ¹H NMR (400 MHz, CDCl₍₃₎) δ 8.82 (s, 1H), 7.71 (s, 2H), 7.65-7.60 (m, 2H), 7.39 (m, 1H), 7.05 (m, 1H), 6.98 (s, 1H), 4.04 (m, 4H), 2.65-2.35 (m, 12H) 1.71 (m, 4H) 1.43-1.25 (m, 8H) ppm; ¹³C NMR (100 MHz, CDCl₍₃₎) δ 157.4, 155.7, 137.5, 134.0, 133.4, 131.5, 129.8, 129.6, 129.5, 126.6, 126.5, 125.1, 123.1, 123.0, 118.0, 116.2, 111.2, 109.6, 105.9, 68.9, 52.3, 47.9, 33.5, 29.4, 21.6, 20.8, 20.4 ppm; GC-MS m/z=484 (M+); Anal. Calcd for C₃₂H₃₆O₄: C, 79.31; H, 7.49. Found: C, 79.34; H, 7.58.

### Preparative Example 6: Preparation of Epoxy Resin 1-6

In the presence of TBAB (tetra-n-butylammonium bromide), benz[a]anthracene-5,9-diol (26 g, 0.1 mol) and an excess (300 g) of 2-(4-chlorobutyl) oxirane were heated (to 90° C.) under solvent-free conditions for 6 hours and then cooled to room temperature, followed by removing the remaining unreacted 2-(4-chlorobutyl) oxirane using a Kugelrohr distiller. An aqueous NaOH solution and toluene were then added to a resulting product obtained through synthesis, followed by heating to 90° C. for 4 hours, thereby preparing an epoxy resin represented by Formula 1-6 in 70% yield through intramolecular Williamson ether synthesis.

¹H NMR (400 MHz, CDCl₍₃₎) δ 8.93 (s, 1H), 8.12 (m, 2H), 7.88 (s, 1H), 7.81 (s, 1H), 7.22 (s, 1H), 7.05-6.97 (m, 2H), 4.08 (m, 4H), 2.60-2.35 (m, 6H) 1.71 (m, 4H) 1.42-1.25 (m, 8H) ppm;

¹³C NMR (100 MHz, CDCl₍₃₎) δ 157.3, 150.5, 134.0, 132.4, 129.8, 129.6, 129.5, 128.3, 126.6, 125.1, 123.1, 123.0, 122.4, 118.0, 111.2, 109.6, 105.9, 68.9, 52.3, 52.1, 47.9, 33.5, 33.2, 29.4, 29.3, 21.6 ppm; GC-MS m/z=456 (M+); Anal. Calcd for C₃₀H₃₂O₄: C, 78.92; H, 7.06. Found: C, 78.77; H, 7.39.

Details of components used in Examples and Comparative Examples are as follows:
(A) Epoxy resin
(A1)-(A6) The epoxy resins prepared in Preparative Examples 1 to 6
(A7) Epoxy resin represented by the following Formula:

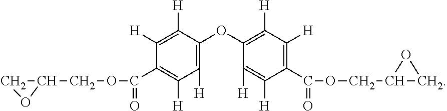 [SMILES: O=C(OCC1CO1)c1ccc(Oc2ccc(C(=O)OCC3CO3)cc2)cc1]

(A8) Biphenyl epoxy resin (NC-3000, Nippon Kayaku Co. Ltd.)
(A9) Anthracene epoxy resin (YX-8800, Mitsubishi Chemical Co. Ltd.)
(B) Curing agent
(B1) KPH-F3065 (Xylok type phenol resin, Kolon Industry Co. Ltd.)
(B2) MEH-7851 (Phenol-aralkyl phenol resin, Meiwa Co. Ltd.)
(C) Curing catalyst
Triphenylphosphine (Hokko Chemical Co. Ltd.)
(D) Inorganic fillers: Mixture of spherical molten alumina having an average particle diameter (D50) of 20 μm, and spherical molten alumina having an average particle diameter (D50) of 0.5 μm (weight ratio: 9:1)
(E) Coupling agent
(E1) Methyltrimethoxysilane (SZ-6070, Dow Corning)
(E2) KBM-573 (N-phenyl-3-aminopropyltrimethoxysilane, Shin-Etsu Chemical Co. Ltd.)
(F) Colorant: Carbon black (MA-600B, Mitsubishi Chemical Co. Ltd.)

### Examples 1 to 7 and Comparative Examples 1 to 5

The aforementioned components were uniformly mixed in amounts shown in Table 1 below (unit: parts by weight) in a Henschel mixer (KSM-22, Keumsung Machinery Co., Ltd.) at a temperature in a range of 25° C. to 30° C. for 30 min. Thereafter, the mixture was subjected to melt-kneading in a continuous kneader at a temperature of up to 110° C. for 30 min, cooled to a temperature of 10° C. to 15° C., and pulverized, thereby preparing epoxy resin compositions for encapsulation of semiconductor devices. In Table 1 below, “-” means that a corresponding component was not used.

Each of the epoxy resin compositions prepared in the Examples and the Comparative Examples was evaluated as to the following properties. Results are shown in Table 1 below.

(1) Fluidity (spiral flow length, unit: inch): Using a low-pressure transfer molding machine, each of the prepared epoxy resin compositions was injected into a mold for measurement of fluidity under conditions of a mold temperature of 175° C., a load of 70 kgf/cm², an injection pressure of 9 MPa, and a curing time of 90 seconds in accordance with EMMI-1-66, followed by measurement of flow length. A greater flow length indicates better fluidity.

(2) Toughness (unit: kgf/mm²): In accordance with ASTM D-790, a standard specimen (size: 125 mm×12.6 mm×6.4 mm (length×width×thickness)) was prepared from each of the prepared epoxy resin compositions and was cured at 175° C. for 4 hours, followed by measurement of toughness of the specimen at 25° C. by a 3-point bending test method using a Universal Testing Machine (UTM).

(3) Thermal conductivity (unit: W/m·K): Thermal conductivity was measured on a specimen prepared from each of the prepared epoxy resin compositions at 25° C. in accordance with ASTM D5470. Specifically, a specimen for measurement of thermal conductivity was prepared in accordance with ASTM D5470 by injecting each of the epoxy resin compositions into a transfer molding machine under conditions of a mold temperature of 175° C., an injection pressure of 9 MPa, and a curing time of 120 seconds. Thereafter, thermal conductivity of the specimen was measured at 25° C. using a flash laser thermal conductivity meter (LFA467, NETZSCH Group).

(4) Reliability (Unit: number): A semiconductor package manufactured using each of the prepared epoxy resin compositions was dried at 125° C. for 24 hours, and then subjected to a thermal shock test of 5 cycles (1 cycle being defined as leaving the package at −65° C. for 10 minutes, at 25° C. for 10 minutes, and at 150° C. for 10 minutes). Thereafter, the presence of external cracks was observed under an optical microscope after pre-conditioning treatment in which a process of leaving the package at 85° C. and 60% RH for 168 hours, followed by IR reflow at 260° C. for 30 seconds was repeated three (3) times. Thereafter, the presence of delamination between the epoxy resin composition and a lead frame was evaluated by scanning acoustic microscopy (C-SAM), which is a non-destructive testing method. Generation of external cracks in a semiconductor package, or occurrence of delamination between the epoxy resin composition and the lead frame, indicate that the corresponding semiconductor package had poor reliability.

TABLE 1

| | | Example | | | | | | | Comparative Example | | | | |
|---|---|---|---|---|---|---|---|---|---|---|---|---|---|
| | | 1 | 2 | 3 | 4 | 5 | 6 | 7 | 1 | 2 | 3 | 4 | 5 |
| A | A1 | 5.2 | 5.2 | — | — | — | — | — | — | — | — | — | — |
| | A2 | — | — | 5.2 | — | — | — | — | — | — | — | — | — |
| | A3 | — | — | — | 5.2 | — | — | — | — | — | — | — | — |
| | A4 | — | — | — | — | 5.2 | — | — | — | — | — | — | — |
| | A5 | — | — | — | — | — | 5.2 | — | — | — | — | — | — |
| | A6 | — | — | — | — | — | — | 5.2 | — | — | — | — | — |
| | A7 | — | — | — | — | — | — | — | 5.2 | 5.2 | — | — | — |
| | A8 | — | — | — | — | — | — | — | — | — | 5.2 | 5.2 | — |
| | A9 | — | — | — | — | — | — | — | — | — | — | — | 5.2 |
| B | B1 | 4.4 | — | 4.4 | 4.4 | 4.4 | 4.4 | 4.4 | 4.4 | — | 4.4 | — | 4.4 |
| | B2 | — | 4.4 | — | — | — | — | — | — | 4.4 | — | 4.4 | — |
| C | | 0.5 | 0.5 | 0.5 | 0.5 | 0.5 | 0.5 | 0.5 | 0.5 | 0.5 | 0.5 | 0.5 | 0.5 |
| D | | 89 | 89 | 89 | 89 | 89 | 89 | 89 | 89 | 89 | 89 | 89 | 89 |
| E | E1 | 0.2 | 0.2 | 0.2 | 0.2 | 0.2 | 0.2 | 0.2 | 0.2 | 0.2 | 0.2 | 0.2 | 0.2 |
| | E2 | 0.2 | 0.2 | 0.2 | 0.2 | 0.2 | 0.2 | 0.2 | 0.2 | 0.2 | 0.2 | 0.2 | 0.2 |
| F | | 0.5 | 0.5 | 0.5 | 0.5 | 0.5 | 0.5 | 0.5 | 0.5 | 0.5 | 0.5 | 0.5 | 0.5 |
| Total | | 100 | 100 | 100 | 100 | 100 | 100 | 100 | 100 | 100 | 100 | 100 | 100 |
| Fluidity | | 65 | 63 | 67 | 69 | 70 | 68 | 67 | 67 | 67 | 65 | 65 | 66 |
| Toughness | | 0.72 | 0.78 | 0.71 | 0.88 | 0.83 | 0.72 | 0.70 | 0.49 | 0.52 | 0.45 | 0.50 | 0.46 |
| Thermal conductivity | | 6.1 | 6.3 | 6.5 | 6.2 | 6.3 | 6.2 | 6.2 | 5.1 | 5.3 | 4.5 | 4.7 | 4.5 |
| Reliability | External | 0 | 0 | 0 | 0 | 0 | 0 | 0 | 10 | 8 | 15 | 10 | 8 |
| | cracks | | | | | | | | | | | | |
| | Delamination | 0 | 0 | 0 | 0 | 0 | 0 | 0 | 2 | 2 | 2 | 1 | 2 |
| | Number | 88 | 88 | 88 | 88 | 88 | 88 | 88 | 88 | 88 | 88 | 88 | 88 |
| | of tested | | | | | | | | | | | | |
| | package | | | | | | | | | | | | |
| | specimens | | | | | | | | | | | | |

As shown in Table 1 above, the epoxy resin compositions of the Examples exhibited high thermal conductivity to secure desired or improved heat dissipation, and could improve reliability through improvement in toughness.

Conversely, the epoxy resin compositions of the Comparative Examples prepared without using the epoxy resin represented by Formula 1 had substantially lower thermal conductivity and toughness than the epoxy resin compositions of the Examples, and thus did not exhibit any improvement in heat dissipation and reliability.

It should be understood that various modifications, changes, alterations, and equivalent example embodiments can be made by those skilled in the art without departing from the spirit and scope of the disclosure.

What is claimed is:

1. An epoxy resin composition for encapsulation of semiconductor devices, the epoxy resin composition comprising:
an epoxy resin;
a curing agent;
an inorganic filler; and
a curing catalyst;
wherein the epoxy resin comprises an epoxy resin represented by Formula 1: 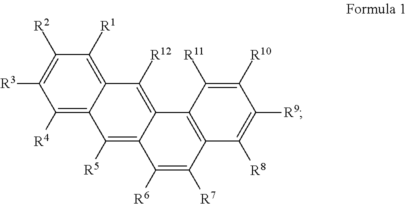
where R¹ to R¹² each independently comprises hydrogen, a substituted or unsubstituted C₁ to C₂₀ alkyl group, a substituted or unsubstituted C₆ to C₃₀ aryl group, a substituted or unsubstituted C₆ to C₃₀ aryloxy group, a substituted or unsubstituted C₃ to C₃₀ heteroaryl group, a substituted or unsubstituted C₃ to C₃₀ heterocycloalkyl group, a substituted or unsubstituted C₇ to C₃₀ arylalkyl group, a substituted or unsubstituted C₁ to C₃₀ heteroalkyl group, or a compound represented by Formula 2,
at least two of R¹ to R¹² comprising a compound represented by Formula 2: 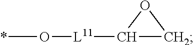
wherein * is a linking site of an element and L¹¹ comprises a substituted or unsubstituted C₄ to C₁₀ alkylene group.

2. The epoxy resin composition as claimed in claim 1, wherein:
at least one of R¹ to R⁴ in Formula 1 comprises a compound represented by Formula 2; and
at least one of R⁸ to R¹¹ in Formula 1 comprises a compound represented by Formula 2, or at least one of R⁶ to R⁷ in Formula 1 comprises a compound represented by Formula 2.

3. The epoxy resin composition as claimed in claim 1, wherein:
R¹ to R¹² in Formula 1 each independently comprises hydrogen, a substituted or unsubstituted C₁ to C₂₀ alkyl group, or a compound represented by Formula 2, and
at least two of R¹ to R¹² comprise a compound represented by Formula 2.

4. The epoxy resin composition as claimed in claim 1, wherein the epoxy resin represented by Formula 1 comprises at least one of compounds represented by Formulas 1-1 to 1-6:

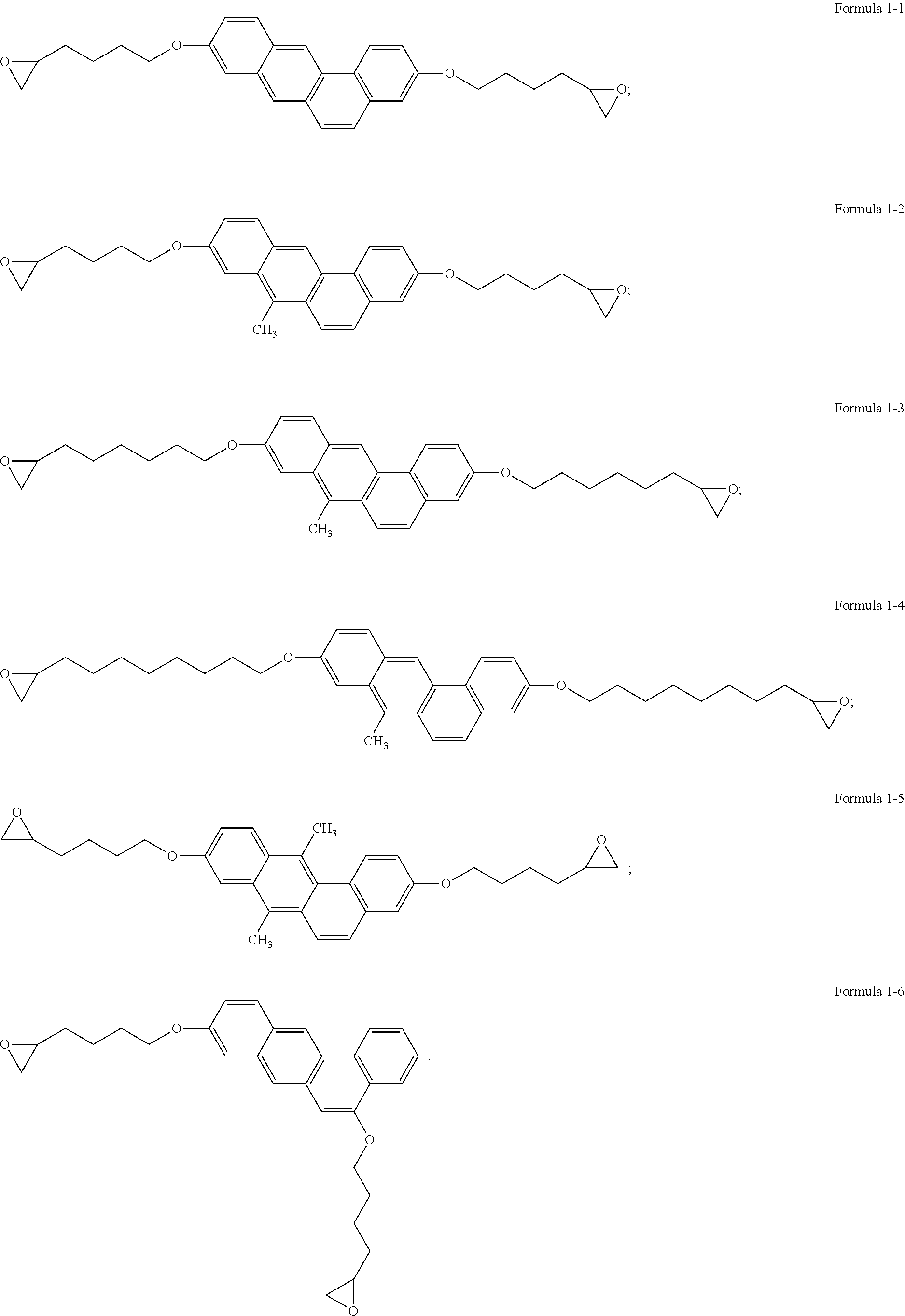 [SMILES: c1cc2cc3c(ccc4cc(OCCCCC5CO5)ccc43)cc2cc1OCCCCC1CO1 ; Cc1c2cc(OCCCCC3CO3)ccc2cc2c1ccc1cc(OCCCCC3CO3)ccc12 ; Cc1c2cc(OCCCCCCC3CO3)ccc2cc2c1ccc1cc(OCCCCCCC3CO3)ccc12 ; Cc1c2cc(OCCCCCCCCC3CO3)ccc2cc2c1ccc1cc(OCCCCCCCCC3CO3)ccc12 ; Cc1c2cc(OCCCCC3CO3)ccc2c(C)c2c1ccc1cc(OCCCCC3CO3)ccc12 ; c1ccc2c(c1)c(OCCCCC1CO1)cc1cc3cc(OCCCCC4CO4)ccc3cc12]

5. The epoxy resin composition as claimed in claim 1, wherein the epoxy resin represented by Formula 1 is present in an amount in a range of about 0.1 wt % to about 17 wt % in the epoxy resin composition for encapsulation of semiconductor devices.

6. The epoxy resin composition as claimed in claim 1, wherein the inorganic fillers comprise alumina.

7. The epoxy resin composition as claimed in claim 1, comprising:
about 2 wt % to about 17 wt % of the epoxy resin;
about 0.5 wt % to about 13 wt % of the curing agent;
about 50 wt % to about 95 wt % of the inorganic fillers; and
about 0.01 wt % to about 5 wt % of the curing catalyst.

8. A semiconductor device encapsulated using the epoxy resin composition for encapsulation of semiconductor devices as claimed in claim 1.
